(19) United States
(12) Patent Application Publication
(10) Pub. No.: US 2015/0090134 A1
(43) Pub. Date: Apr. 2, 2015

(54) METHOD AND APPARATUS FOR PRINTING SMALL ASPECT FEATURES

(71) Applicant: Illinois Tool Works Inc., Glenview, IL (US)

(72) Inventors: Zhuoyun Li, North Grafton, MA (US); Boris Shifrin, Framingham, MA (US); John George Klauser, Holliston, MA (US); Aditya Ajit Kulkarni, Franklin, MA (US)

(73) Assignee: Illinois Tool Works Inc., Glenview, IL (US)

(21) Appl. No.: 14/041,287

(22) Filed: Sep. 30, 2013

(51) Int. Cl. H05K 3/12

(52) U.S. Cl. CPC H05K 3/1233
USPC 101/123; 101/129

(57) ABSTRACT

A method of stencil printing small aspect features includes performing a stencil print stroke across a stencil having at least one small aspect opening with a stencil printer having a squeegee blade, and venting an area below the at least one small aspect opening. Another method includes performing a stencil print stroke across a stencil having at least one small aspect opening with a stencil printer having a multi-blade squeegee, and venting an area below the at least one small aspect opening. A stencil printer includes a stencil having apertures formed therein, and a print head positioned over the stencil and configured to deposit viscous material within the apertures of the stencil. The print head includes a support, a first pair of blades secured to the support, and a second pair of blades secured to the support.

### BACKGROUND OF THE DISCLOSURE

In manufacturing a surface-mount printed circuit board, a stencil printer can be used to print solder paste onto the circuit board. Typically, a circuit board having a pattern of pads or some other conductive surface onto which solder paste will be deposited is automatically fed into the stencil printer; and one or more small holes or marks (known as “fiducials”) on the circuit board are used to properly align the circuit board with the stencil or screen of the stencil printer prior to printing solder paste onto the circuit board. In some systems, an optical alignment system is used to align the circuit board with the stencil.

Once the circuit board has been properly aligned with the stencil in the printer, the circuit board is raised to the stencil, solder paste is dispensed onto the stencil, and a wiper blade (or squeegee) traverses the stencil to force the solder paste through apertures in the stencil and onto the board. As the squeegee is moved across the stencil, the solder paste tends to roll in front of the blade, which desirably causes mixing and shearing of the solder paste so as to attain a desired viscosity to facilitate filling of the apertures in the screen or stencil. The solder paste typically is dispensed onto the stencil from a standard cartridge.

In some stencil printers, any excess solder paste remaining under the squeegee, after it has fully traversed the stencil, remains on the stencil when the squeegee is returned to its initial position for printing on a second circuit board. In some stencil printers, a second squeegee moves across the stencil in the direction opposite to that of the first squeegee. The first squeegee and the second squeegee are used on alternating boards to continually pass the roll of solder paste over the apertures of a stencil to print on each successive circuit board. In the stencil printers that utilize two squeegees, there is still the problem that at the end of a manufacturing day, or when the stencil is to be changed, which is excess solder paste typically remains on the stencil and must be manually removed. Also, in these known printers, it is difficult to maintain a desirable viscosity because volatile solvents escape from the solder paste, thereby affecting the viscosity of the solder paste.

In these stencil printers, the squeegee blades are typically at a predetermined angle with respect to the stencil to apply downward pressure on the solder paste to force the solder paste through the apertures in the stencil as the squeegee is moved across the stencil. The angle of the blade is selected based on the speed at which the blade traverses the stencil and based on the desired downward pressure on the solder paste from the blade. It is desirable to maintain a consistent pressure on the solder paste as the squeegee traverses the stencil.

Over the years, smaller devices are being mounted on circuit boards, which require solder paste deposits having small aspect features to be printed on the circuit boards. The surface mount technology (“SMT”) industry has been working to improve the ability to print small solder paste deposits having low area ratios by stencil printers. Low area ratio deposits (e.g., less than 0.5) typically cause low solder paste transfer volume, which result in higher defect rates during the circuit board assembly process.

### SUMMARY OF THE DISCLOSURE

One aspect of the disclosure is directed to a method of stencil printing small aspect features. In one embodiment, the method comprises: performing a stencil print stroke across a stencil having at least one small aspect opening with a stencil printer having a squeegee blade; and venting an area below the at least one small aspect opening.

Embodiments of the method further may include lifting a leading blade of the multi-blade squeegee when the leading blade has passed a target aperture and a trailing blade has not reached the target aperture. The method further may include enabling trapped air to vent out from the underside of the stencil. In certain embodiments, each small aspect opening may have an aperture size of less than 0.2 mm, a pitch of less than 0.4 mm, and an area ratio of less than 0.5. Venting an area below the at least one small aspect opening includes providing protruding bumps on a bottom surface of the stencil adjacent the at least one small aspect opening.

Another aspect of the disclosure is directed to a method comprising: performing a stencil print stroke across a stencil having at least one small aspect opening with a stencil printer having a multi-blade squeegee; and venting an area below the at least one small aspect opening.

Yet another aspect of the disclosure is directed to a stencil printer for printing viscous material on an electronic substrate. In one embodiment, the stencil printer comprises a stencil having apertures formed therein, and a print head positioned over the stencil and configured to deposit viscous material within the apertures of the stencil. The print head includes a support, a first pair of blades secured to the support, and a second pair of blades secured to the support. In one embodiment, the blades are angled to force solder paste through the apertures of the stencil.

### BRIEF DESCRIPTION OF THE DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a front perspective view of a stencil printer of an embodiment of the present disclosure;

FIG. 2 is a schematic representation of a stencil print operation with a single blade squeegee;

FIG. 3 is a schematic representation of a stencil print operation with a multi-blade (two blade) squeegee;

FIG. 4 is a schematic representation of a stencil print operation with a stencil having gaps for venting; and

FIG. 5 is a schematic representation of a multi-blade squeegee of an embodiment of the disclosure.

### DETAILED DESCRIPTION OF THE DISCLOSURE

For purposes of illustration, embodiments of the present disclosure are described below, with reference to a stencil printer used to print solder paste onto a circuit board. The apparatus and associated methods may also be used in other applications requiring dispensing of other viscous or printing materials, such as glues, adhesives, and encapsulants on a variety of substrates. For example, the apparatus may be used to print epoxy for use as underfill for chip-scale packages. Pressurized print heads of embodiments of this disclosure can be used in stencil printers. In certain embodiments, the stencil printer may include an Accela® or Momentum® series stencil printer platform offered by Speedline Technologies, Inc. of Franklin, Mass.

The present disclosure is directed to methods for increasing solder paste transfer volume through small apertures. For example, in one embodiment, the apertures can each have a diameter less than 0.2 mm, a pitch (with pitch being defined as the center of one feature to the center of an adjacent feature) of less than 0.4 mm, and an area ratio (total area of the aperture size divided by the wall area of the aperture) of less than 0.5, by employing a multi-blade squeegee with stencil underside venting within the stencil printer. In a particular embodiment, the apertures can each have a diameter of less than 0.15 mm, a pitch of less than 0.3 mm, and an aspect area ratio of less than 0.375. The multi-blade squeegee increases solder paste volume into the aperture without negatively effecting printing time. The stencil underside venting facilitates the multi-blade squeegee printing by relieving air trapped in the aperture that prevents solder paste from entering apertures. The multi-blade squeegee with stencil underside venting enables solder paste to extend beyond current area ratio limitation, thereby allowing further miniaturization of printed circuit board assemblies. The methods described herein resolve the issue of low solder paste transfer volume when performing a print operation with the stencil printer.

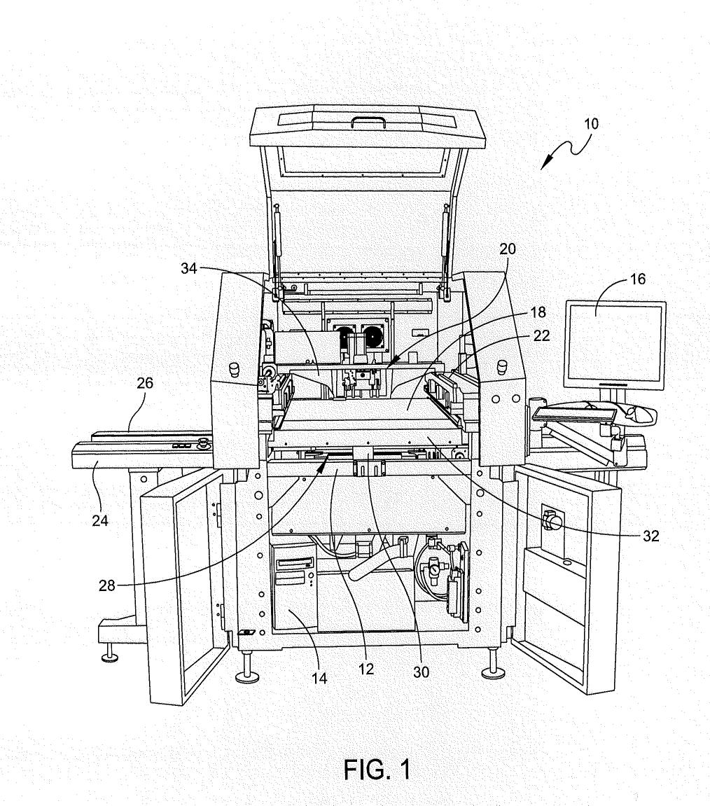

Referring now to the drawings, and more particularly to FIG. 1, there is generally indicated at 10 a stencil printer of an embodiment of the disclosure. As shown, the stencil printer 10 includes a frame 12 that supports components of the stencil printer. The components of the stencil printer may include, in part, a controller 14, a display 16, a stencil 18, and a print head assembly or print head, generally indicated at 20, which is configured to apply the solder paste in a manner described in greater detail below.

As shown in FIG. 1 and described below, the stencil and the print head may be suitably coupled or otherwise connected to the frame 12. In one embodiment, the print head 20 may be mounted on a print head gantry 22, which may be mounted on the frame 12. The print head gantry 22 enables the print head 20 to be moved in the y-axis direction under the control of the controller 14 and to apply pressure on the print head as it engages the stencil 18. As described below in further detail, the print head 20 may be placed over the stencil 18 and may be lowered in the z-axis direction into contact and sealingly engage the stencil.

The stencil printer 10 may also include a conveyor system having rails 24, 26 for transporting a printed circuit board (sometimes referred to as a “printed wiring board,” “substrate,” or “electronic substrate” herein) to a print position in the stencil printer. The rails 24, 26 sometimes may be referred to herein as a “tractor feed mechanism,” which is configured to feed, load or otherwise deliver circuit boards to the working area of the stencil printer, which may be referred to herein as a “print nest,” and to unload circuit boards from the print nest.

The stencil printer 10 has a support assembly 28 to support the circuit board, which raises and secures the circuit board so that it is stable during a print operation. In certain embodiments, the substrate support assembly 28 may further include a particular substrate support system, e.g., a solid support, a plurality of pins or flexible tooling, which is positioned beneath the circuit board when the circuit board is in the print position. The substrate support system may be used, in part, to support the interior regions of the circuit board to prevent flexing or warping of the circuit board during the print operation.

In one embodiment, as will be described in greater detail below, the print head 20 may be configured to receive solder paste from a source, such as a dispenser, e.g., a solder paste cartridge, that provides solder paste to the print head during the print operation. Other methods of supplying solder paste may be employed in place of the cartridge. For example, solder paste may be manually deposited between the blades or from an external source. Additionally, in a certain embodiment, the controller 14 may be configured to use a personal computer having a suitable operating system, such as a Microsoft DOS or Windows XP operating system, with application specific software to control the operation of the stencil printer 10. The controller 14 may be networked with a master controller that is used to control a production line for fabricating circuit boards.

In one configuration, the stencil printer 10 operates as follows. A circuit board is loaded into the stencil printer 10 using the conveyor rails 24, 26. The support assembly 28 raises and secures the circuit board to a print position. The print head 20 is then lowered in the z-axis direction until the blades of the print head contact the stencil 18 at a desired pressure. The print head 20 is then moved in the y-axis direction across the stencil 18 by the print head gantry 22. The print head 20 deposits solder paste through apertures in the stencil 18 and onto the circuit board. Once the print head has fully traversed the stencil 18 across the apertures, the print head is lifted off the stencil and the circuit board is lowered back onto the conveyor rails 24, 26. The circuit board is released and transported from the stencil printer 10 so that a second circuit board may be loaded into the stencil printer. To print on the second circuit board, the print head is lowered in the z-axis direction into contact with the stencil and moved across the stencil 18 in the direction opposite to that used for the first circuit board.

Still referring to FIG. 1, an imaging system 30 may be provided for the purposes of aligning the stencil 18 with the circuit board prior to printing and to inspect the circuit board after printing. In one embodiment, the imaging system 30 may be disposed between the stencil 18 and the support assembly 28 upon which a circuit board is supported. The imaging system 30 is coupled to an imaging gantry 32 to move the imaging system. In one embodiment, the imaging gantry 32 may be coupled to the frame 12, and includes a beam that extends between side rails of the frame 12 to provide back and forth movement of the imaging system 30 over the circuit board in a y-axis direction. The imaging gantry 32 further may include a carriage device, which houses the imaging system 30, and is configured to move along the length of the beam in an x-axis direction. The construction of the imaging gantry 32 used to move the imaging system 30 is well known in the art of solder paste printing. The arrangement is such that the imaging system 30 may be located at any position below the stencil 18 and above the circuit board to capture an image of predefined areas of the circuit board or the stencil, respectively. In other embodiments, when positioning the imaging system outside the print position the imaging system may be located above or below the stencil and the circuit board.

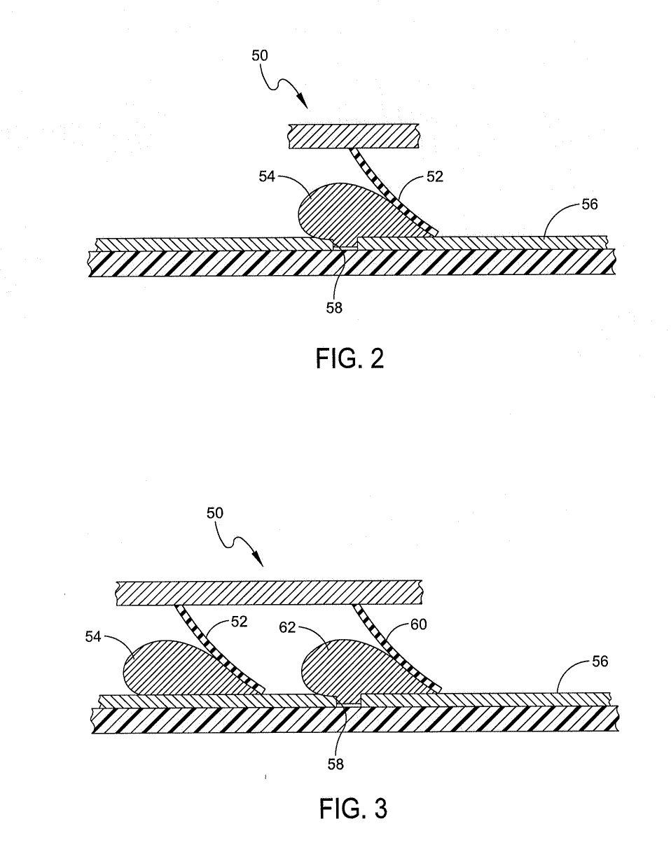

Performing the method described herein includes two aspects: 1) employing a print head having a multi-blade squeegee and 2) providing stencil underside venting. These two aspects of the invention are performed to achieve the increased transfer volume of solder paste. FIG. 2 illustrates a multi-blade squeegee, generally indicated at 50, having a leading blade 52, which moves a bead of solder paste 54 across a top surface of a stencil 56. In one embodiment, the multi-blade squeegee 50 includes four blades with one set of two blades capable of dispensing solder paste when moving the print head in one direction and a second set of two blades capable of dispensing solder paste when moving the print head in an opposite direction. In another embodiment, the multi-blade squeegee 50 includes six blades, with one set of three blades and another set of three blades. As shown, the leading blade 52 traverses across the stencil 56, moving a bead of solder paste 54 in the traditional manner. The leading blade 52 is angled to force the solder paste into an aperture 58 formed in the stencil.

FIG. 3 illustrates two blades (the leading blade 52 and a trailing blade 60) of the multi-blade squeegee 50 during the print process. As shown, the trailing blade 60 moves another bead of solder paste 62 having a corresponding amount of solder paste to increase transfer volume within the aperture 58 of the stencil 56. The trailing blade 60 functions to completely (or nearly completely) fill the aperture 58 during the print process. With squeegees having six blades, a third blade, which constitutes the trailing blade, may be further provided to increase the volume transfer of the solder paste into the aperture 58 of the stencil 56 during the stencil print process.

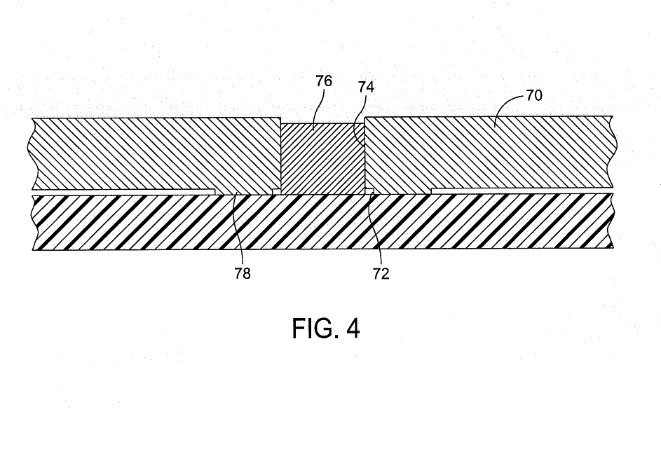

FIG. 4 illustrates a stencil 70 having gaps 72 around an aperture 74 for underside venting. Stencil underside venting enables air trapped within the stencil aperture 74 (especially in low area ratio and/or narrow apertures) to vent. This better enables solder paste to fill the aperture 74 when solder paste 76 moves over the aperture with the additional squeegee blades (e.g., 2nd, 3rd . . . ). In certain embodiments, underside venting may be used with pressurized print heads.

To achieve the stencil underside venting, one of two approaches may be employed. A first method involves lifting the leading blade of the multi-blade squeegee when the leading blade has passed the target aperture and the trailing blade has not yet reached the target aperture. The relief of down pressure exerted on stencil by multi-blade squeegee will allow trapped air to vent out from the underside of the stencil. Then continuing with printing will result in improved solder paste filling ratio as show in above table. This solution, while simple and effective, has the two disadvantages—increased time in printing process; and indiscriminately venting of all apertures on stencil, which can be undesirable in certain applications.

A second method involves providing underside protruding bump 78, which are positioned near target apertures, e.g., aperture 74, on the stencil 70. As shown, the bump 78 projects downwardly from the underside of the stencil 70 from an area surrounding the aperture. This solution has the following advantages—no time penalty in the printing process; allows targeted venting for apertures that need venting; and functions well with 1 to N numbers of squeegee blades design.

A third method is to have a serrated or roughened surface on the underside of the stencil. In another embodiment, channels may be formed in the bottom surface of the stencil to create the space around the aperture. Other methods of creating space around the aperture may also be employed.

The multiple fill action coupled with stencil underside venting between the blades of the multi-blade squeegee will result in higher solder paste transfer volume as shown below:

| | |
|---|---|
| Single blade | Multi-blade (2 blades) |
| squeegee results | squeegee results |

| Feature Area | Transfer | | Transfer | |
|---|---|---|---|---|
| Ratio | Volume | Cpk | Volume | Cpk |
| 0.375 | 60% | 0.28 | 84% | 1.1 |
| 0.5 | 78% | 1.23 | 93% | 1.6 |

As shown, the multi-blade squeegee design increases the solder transfer volume significantly. This increase push the process for low area ratio feature from process incapable (Cpk<1) to process capable (Cpk>1)

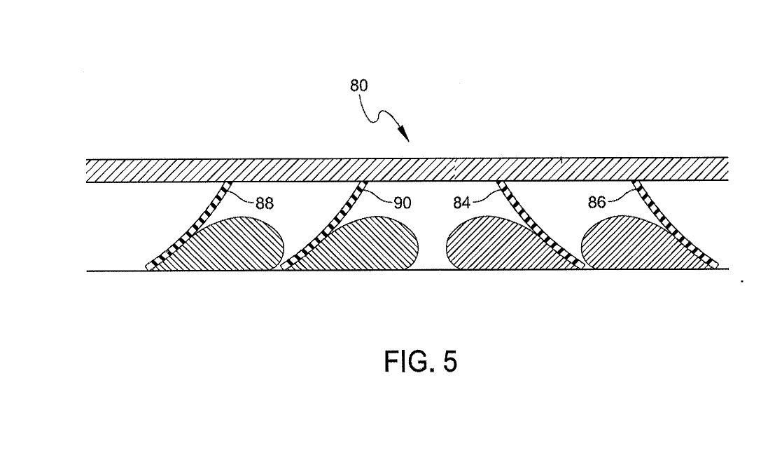

FIG. 5 illustrates a multi-blade squeegee assembly, generally indicated at 80, of an exemplary embodiment of the present disclosure. As shown, the squeegee assembly includes a support 82 and four blades 84, 86, 88, 90, each being secured to the support. As shown, a first set of blades, e.g., blades 84, 86, is angled in one direction to force solder paste into the apertures when moving the squeegee assembly in a first direction. A second set of blades, e.g., blades 88, 90, is angled in an opposite direction to force solder paste into the apertures when moving the squeegee assembly in a second, opposite direction.

The configuration of the multi-blade squeegee with underside venting also provides the benefits of—no throughput (cycle time) penalty with multiple printing action in one print pass; adding squeegee blades is a relatively low cost solution to increase transfer volume; scalable design allows blade number expansion; and simplistic design approach allows retro-fit possibilities.

Embodiments are not limited in their application to the details of construction and the arrangement of components set forth in the following description or illustrated in the drawings. Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

Having thus described several aspects of at least one embodiment, it is to be appreciated various alterations, modifications, and improvements will readily occur to those skilled in the art. Such alterations, modifications, and improvements are intended to be part of this disclosure, and are intended to be within the scope of the invention. Accordingly, the foregoing description and drawings are by way of example only.

What is claimed is:

1. A method of stencil printing solder paste deposits having small aspect features on an electronic substrate, the method comprising:
performing a stencil print stroke of solder paste across a stencil having at least one small aspect opening with a stencil printer having a squeegee blade configured to move solder paste across the stencil; and
venting an area below the at least one small aspect opening,
wherein the small aspect openings each have an aperture size of less than 0.2 mm.

2. (canceled)

3. The method of claim 1, wherein the small aspect openings each have a pitch of less than 0.4 mm.

4. The method of claim 3, wherein the small aspect openings each have an area ratio of less than 0.5.

5. The method of claim 1, wherein venting an area below the at least one small aspect opening includes providing protruding bumps on a bottom surface of the stencil adjacent the at least one small aspect opening.

6. The method of claim 1, further comprising lifting a leading blade of a multi-blade squeegee when the leading blade has passed a target aperture and a trailing blade has not reached the target aperture.

7. The method of claim 6, further comprising enabling trapped air to vent out from the underside of the stencil.

8. A method of stencil printing solder paste deposits having small aspect features on an electronic substrate, the method comprising:
performing a stencil print stroke of solder paste across a stencil having at least one small aspect opening with a stencil printer having a multi-blade squeegee configured to move solder paste across the stencil; and
venting an area below the at least one small aspect opening,
wherein the small aspect openings each have an aperture size of less than 0.2 mm.

9. (canceled)

10. The method of claim 8, wherein the small aspect openings each have a pitch of less than 0.4 mm.

11. The method of claim 10, wherein the small aspect openings each have an area ratio of less than 0.5.

12. The method of claim 8, wherein venting an area below the at least one small aspect opening includes providing protruding bumps on a bottom surface of the stencil adjacent the at least one small aspect opening.

13. The method of claim 8, further comprising lifting a leading blade of the multi-blade squeegee when the leading blade has passed a target aperture and a trailing blade has not reached the target aperture.

14. The method of claim 13, further comprising enabling trapped air to vent out from the underside of the stencil.

15. A stencil printer for printing viscous material on an electronic substrate, the stencil printer comprising:
a stencil having apertures formed therein; and
a print head positioned over the stencil and configured to deposit viscous material within the apertures of the stencil, the print head including a support, a first pair of blades secured to the support, and a second pair of blades secured to the support.

16. The stencil printer of claim 15, wherein the blades are angled to force solder paste through the apertures of the stencil.
